(19) United States
(12) Patent Application Publication
(10) Pub. No.: US 2025/0012842 A1
(43) Pub. Date: Jan. 9, 2025

(54) MEASUREMENT OF A QUALITY INDICATOR FOR AN ELECTRICAL INSULATOR

(71) Applicant: Megger Instruments Ltd, Dover (GB)

(72) Inventors: Stanislaw ZUREK, Dover (GB); Paul SWINERD, Dover (GB); Mark TUTTON, Dover (GB); Richard WARDAK, Dover (GB); Clive TAYLOR, Fort Collins, CO (US)

(21) Appl. No.: 18/892,027

(22) Filed: Sep. 20, 2024

Related U.S. Application Data
(63) Continuation of application No. PCT/GB2023/050717, filed on Mar. 21, 2023.

(30) Foreign Application Priority Data
Mar. 23, 2022 (GB) 2204057.0

(51) Int. Cl. G01R 31/14

(52) U.S. Cl. CPC G01R 31/14

(57) ABSTRACT

Measurement apparatus performs a measurement of a quality indicator for an electrical insulator comprising a ratio of a first value of an electrical parameter at a first time to a second value at a second time. An output from an electrical circuit for measuring the electrical parameter for the electrical insulator is sampled to produce at least one sample and steps of sampling the output from the electrical circuit are performed to produce one or more further samples at successive increments in time and at least some of the samples are processed to generate an approximate function relating the measured electrical parameter to time. A predicted value is calculated for the quality indicator on a basis comprising the electrical parameter indicated by the approximate function for the second time and an electrical signal is generated indicating a state of the measurement based on at least the predicted value of the quality indicator.

### CROSS-REFERENCE TO RELATED APPLICATIONS

This application is a continuation under 35 U.S.C. § 120 of International Application No. PCT/GB2023/050717, filed Mar. 21, 2023, which claims priority to GB Application No. GB 2204057.0, filed Mar. 23, 2022, under 35 U.S.C. § 119 (a). Each of the above-referenced patent applications is incorporated by reference in its entirety.

### TECHNICAL FIELD

The present invention relates generally to an improved method of operation for a measurement apparatus and to an improved measurement apparatus for measuring a quality indicator for an electrical insulator, the quality indicator comprising a ratio of a first value of an electrical parameter at a first time to a second value of the electrical parameter at a second time. For example, the quality indicator may be a Polarisation Index (PI) or a Dielectric Absorption Ratio (DAR), and the electrical parameter may be resistance.

### BACKGROUND

A quality indicator for an electrical insulator, for example a Polarisation Index (PI) or a Dielectric Absorption Ratio (DAR) comprises a ratio of a first value of an electrical parameter at a first time to a second value of the electrical parameter at a second time. The electrical parameter is typically resistance. The quality indicator may be used to assess the condition of an electrical insulator. The degree to which the measured resistance varies between the first time and the second time may give useful information as to whether an insulator is safe or hazardous. In an example, a first measurement of resistance may be taken one minute after a voltage is applied to an insulator, and a second measurement of resistance may be taken 10 minutes after the voltage is applied. It may be necessary to make several measurements of the quality indicator at an installation, for example for different phase windings of an electric motor, so that the test process may be particularly time consuming.

### SUMMARY

In accordance with a first aspect, there is provided a method of operation of a measurement apparatus for performing a measurement of a quality indicator for an electrical insulator, the quality indicator comprising a ratio of a first value of an electrical parameter at a first time to a second value of the electrical parameter at a second time, the method comprising:
sampling an output from an electrical circuit for measuring the electrical parameter for the electrical insulator to produce at least one sample;
performing steps of sampling the output from the electrical circuit to produce one or more further samples at successive increments in time and processing at least some of the samples to generate an approximate function relating the measured electrical parameter to time;
calculating a predicted value for the quality indicator on a basis comprising the electrical parameter indicated by the approximate function for the second time; and
generating an electrical signal indicating a state of the measurement based on at least the predicted value of the quality indicator.

This feature allows a shorter measurement time by use of the predicted value of the quality indicator instead of a measured value at the second time and allows the measurement time to be adjusted in dependence on the predicted value. It has been found that the time taken to achieve a reliable estimate of the predicted value of the quality indicator is dependent on the predicted value.

In examples, the electrical parameter may be resistance or current.

In an example, the method comprises generating a measure of confidence in the predicted value of the quality indicator, wherein the step of generating an electrical signal indicating a state of the measurement is based on at least the measure of confidence in the predicted value of the quality indicator.

This feature allows a shorter measurement time by reducing the measurement time in dependence on the measure of confidence in the predicted value of the quality indicator.

In an example, the measure of confidence in the predicted value of the quality indicator is a confidence range of the predicted value of the quality indicator based on a measure of noise for at least some of the samples.

This feature provides an efficient method of generating the measure of confidence in the predicted value of the quality indicator.

In an example, the electrical signal indicating a state of the measurement indicates that the measurement is complete.

This feature allows the measurement to be taken before the second time is reached.

In an example, the method comprises stopping the measurement in response to the electrical signal indicating a state of the measurement.

This feature allows the measurement to be automatically stopped before the second time.

In an example, the method comprises generating an electrical signal causing display of the predicted value for the quality indicator in dependence on the electrical signal indicating the state of the measurement.

In an example, said processing some of the samples to generate an approximate function relating measured resistance to time comprises discarding a set of samples.

This feature allows an accurate predicted value for the quality indicator to be generated, for example by discarding initial samples.

In example, said processing at least some of the samples to generate an approximate function relating measured resistance to time comprises least squares curve fitting, linear regression and/or non-linear regression.

This feature allows efficient and convenient generation of the approximate function.

The quality indicator for the electrical insulator may be for example a polarisation index or a dielectric absorption ratio.

In accordance with a second aspect, there is provided measurement apparatus for performing a measurement of a quality indicator for an electrical insulator, the quality indicator comprising a ratio of a first value of an electrical parameter at a first time to a second value of the electrical parameter at a second time, the measurement apparatus comprising at least one processor configured to cause the measurement apparatus to:
sample an output from an electrical circuit for measuring the electrical parameter for the electrical insulator to produce at least one sample;
perform steps of sampling the output from the electrical circuit to produce one or more further samples at successive increments in time and processing at least some of the samples to generate an approximate function relating measured the electrical parameter to time;
calculate a predicted value for the quality indicator on a basis comprising a value of the electrical parameter indicated by the approximate function for the second time; and
generate an electrical signal indicating a state of the measurement based on at least the predicted value of the quality indicator.

In accordance with a third aspect, there is provided a computer-readable storage medium holding instructions for causing one or more processors to cause measurement apparatus for performing a measurement of a quality indicator for an electrical insulator, the quality indicator comprising a ratio of a first value of an electrical parameter at a first time to a second value of the electrical parameter at a second time, to:
receive a sample of an output from an electrical circuit for measuring the electrical parameter for the electrical insulator to produce at least one sample;
receive further samples at successive increments in time and process at least some of the samples to generate an approximate function relating the measured electrical parameter to time;
calculate a predicted value for the quality indicator on a basis comprising the electrical parameter indicated by the approximate function for the second time; and
generate an electrical signal indicating a state of the measurement based on at least the predicted value of the quality indicator.

Further features and advantages of the will be apparent from the following description of exemplary embodiments, which are given by way of example only.

### BRIEF DESCRIPTION OF THE DRAWINGS

FIG. 1 is a schematic diagram illustrating a simplified electrical model of an insulator, showing current flow due to leakage, capacitance and absorption;

FIG. 2 is a chart illustrating typical current flow due to leakage, capacitance and absorption as a function of time;

FIG. 3 illustrates the calculation of polarisation index (PI);

FIG. 4 illustrates examples of calculation of polarisation index for various conditions of insulation;

FIG. 5 is an example of a table linking polarisation index values to insulation condition;

FIG. 6 is a schematic diagram illustrating an example of a meter connected to an insulator under test;

FIG. 7 is a schematic diagram illustrating an example of a meter connected to an insulator under test, configured to automatically end a measurement in dependence on a predicted value of a quality indicator;

FIG. 8 is a schematic diagram illustrating an example of a meter connected to an insulator under test, configured to automatically end a measurement in dependence on a measure of confidence in the predicted value of the quality indicator;

FIG. 9 is a schematic diagram illustrating measurement equipment comprising a meter and a user device in communication with the meter.

FIG. 10 is a flow diagram illustrating an example of a method of operating a meter;

FIG. 11 illustrates prediction of a quality indicator indicating “good” insulator condition (PI=3-5);

FIG. 12 illustrates prediction of a quality indicator indicating “bad” insulator condition (PI<2) in a reduced time in comparison to the time for prediction of a quality indicator indicating “good” insulator condition;

FIG. 13 illustrates prediction of a quality indicator indicating “brittle” insulator condition (PI>5);

FIG. 14 illustrates an example of a meter display showing a prediction of a quality indicator from noisy samples.

FIG. 15 is a graph illustrating generating a predicted value of the resistance at the second time;

FIG. 16 shows a meter display for an initial part of the measurement shown complete in FIG. 11;

FIG. 17 shows a meter display for an intermediate part of the measurement shown complete in FIG. 11;

FIG. 18 illustrates a simplified prediction method; and

FIGS. 19a, 19b and 19c illustrate modelling of absorption effects with modelling of an additional RC network for various component values.

### DETAILED DESCRIPTION

By way of example, embodiments will now be described in the context of a digital meter capable of measuring a polarisation index (PI) of an electrical insulator, but it will be understood that embodiments of the invention may relate to other electrical test equipment and that embodiments of the invention are not restricted to measurement of polarisation index. Other quality indicators for an electrical insulator may be measured, where the quality indicator comprises a ratio of a first electrical parameter at a first time to a second electrical parameter at a second time.

A conventional meter for measuring a polarisation index measures the resistance of an insulator at a first time and also measures the resistance of the insulator at a second time, and then calculates the ratio of the measurements. According to the present embodiments, a meter can be configured to reduce measurement time by continually taking samples of resistance during a measurement, and predicting rather than measuring the resistance at the second time on the basis of an extrapolation of samples already taken, and continually updating the predicted value of the quality indicator as the measurement progresses. The quality indicator can be predicted based on the ratio of the extrapolated resistance for the second time and the measured or extrapolated resistance for the first time. It has been found that the reliability of the predicted value of the quality indicator is dependent on the predicted value itself. If the predicted value of quality indicator is found to be either greater than or less than predetermined limits, the measurement can be stopped automatically on the basis that the predicted value is a sufficiently reliable indicator of what the measurement result would be. The predicted value of quality indicator can then be displayed as the measurement result.

A measure of the noise of the samples taken can be used in the process of determining that the predicted value of quality indicator is sufficiently reliable that the measurement can be stopped.

It should be understood that a measurement and prediction of resistance typically comprises a measurement and prediction of current, provided that the applied voltage, which is typically a constant voltage, is known, or known to be the same, for each measurement. Accordingly, references to measurements and predictions of resistance should be interpreted as alternatively referring to measurements and predictions of current. A Polarisation Index may be calculated as a ratio of currents taken with a given applied voltage.

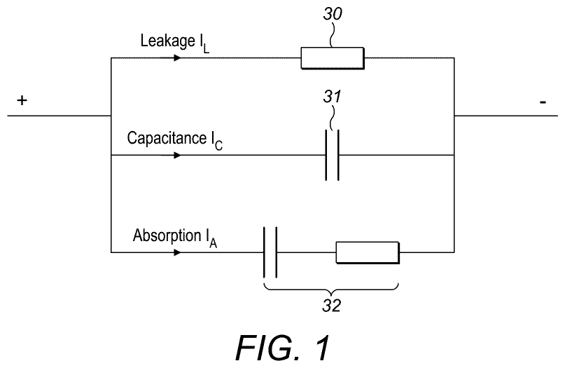

In order to better explain the operation of the meter to predict values of the Polarisation Index (PI), the process of calculating a Polarisation Index will now be explained in more detail. A Polarisation Index (PI) test is typically used for testing the quality of an insulation system, for example in rotating machines and high voltage (HV) cables. An insulating system may in fact be seen as a capacitor, as it comprises at least two conductors separated by an insulator, and can be represented as an equivalent electrical diagram as shown in FIG. 1. The capacitor 31 represents the main capacitance of the system, and the leakage resistor 30 denotes the insulation resistance with the leakage current I_{L} flowing through it.

The insulation quality is measured, for example, by applying a DC voltage, that is to say a voltage that is constant for the test, across the insulation system, between the points denoted by +/− in FIG. 1, and the resulting total applied voltage and the total current are measured accurately. Because the test is carried out with a DC voltage, this voltage across the insulation system may be generated with very high stability, typically better than 1V in 1 kV before the test begins, so that any AC current, for instance due to ripple of the switch-mode power supply, flowing through the capacitance is negligibly small as compared to the DC current of interest.

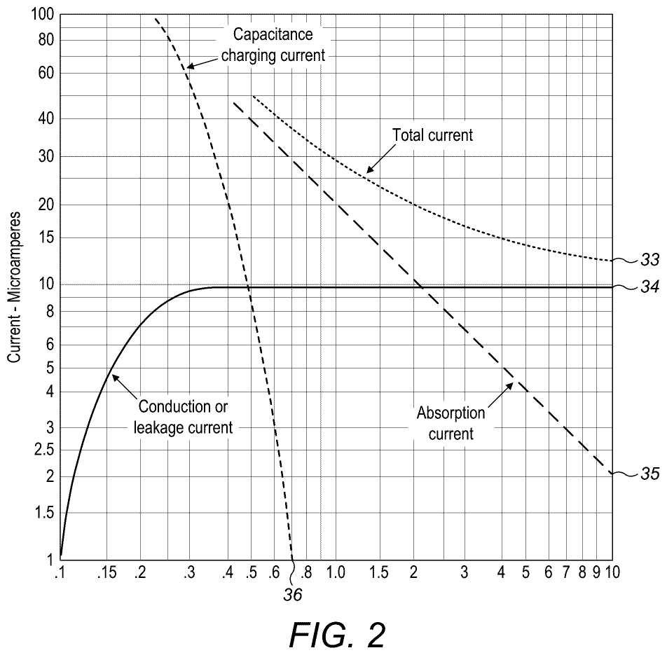

The total current is composed of several components, as shown in FIG. 2, which has a vertical scale showing current and a horizontal scale showing time in seconds. At the moment of applying the test DC voltage, the main capacitor 31 is being charged, which results with very high charging current, as shown by curve 36. Once stable DC voltage is reached when the capacitor 31 is charged the capacitor charging current become negligible. For small capacitance the voltage can be stabilised within less than 1 sec.

With a stable voltage the current through the leakage resistance 30 is constant as shown by curve 34, and the capacitive current drops to a negligible level, as shown by curve 36. However, there is also an additional component called absorption current, shown by curve 35, which decays with a much longer time constant, which may be several minutes, even after the voltage reaches stability. This is modelled in FIG. 1 with the additional RC branch, shown by series capacitor and resistor 32, through which absorption current flows, which gives a much longer RC time constant than the main capacitor. In practice, there can be multiple time constants involved, and this could be modelled as more RC absorption branches in addition to the RC branch 32 shown in FIG. 1. For example, the additional RC branches may be connected in parallel.

The absorption current occurs because the charges are trapped in the body of the insulator, but the applied voltage is able to drag them slowly and displace them locally. These charges behave as if they were suspended on springs and slowly move from their discharged position to the charged position, to achieve balance with the electric field in the body of the insulator. This phenomenon is referred to as electrical induction or electrical polarisation/depolarisation.

More than one time constant may arise, for instance if there is more than one layer of insulation. Each layer behaves as a distinct capacitance, exhibiting slightly different behaviour. The result is that the overall curve does not have a simple exponential shape, but can even have negative curvature, having an accelerating slope rather than decelerating, and may tend to a plateau.

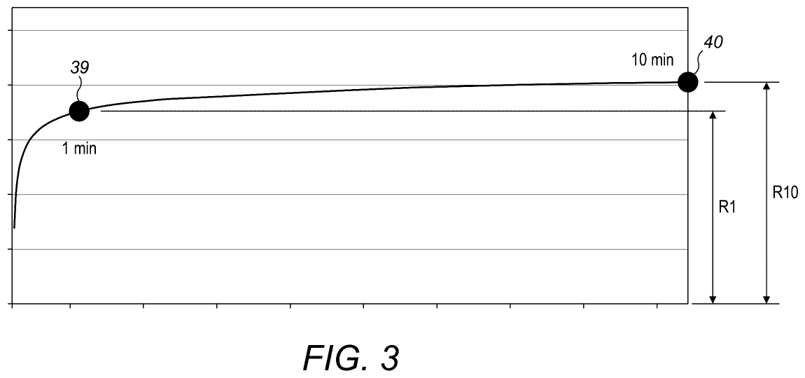

Because the applied voltage is constant, and the resulting current is not, the resistance calculated from Ohm's law R=V/I is changes during the measurement. Because the total current typically reduces during the measurement, as shown by curve 33 in FIG. 2, the measured resistance R is increases. Typical curves of insulation resistance (IR) against time are shown in FIG. 3.

As shown in FIG. 3, the insulation resistance is conventionally measured for 10 minutes, and two values of resistance are extracted: the value at 1 min (R 1 min) 39 and at 10 min (R 10 min) 40. The Polarization Index (PI) is calculated as the ratio between the two numbers, such that PI=R 10 min/R 1 min (R10/R1 in minutes, or R600/R60 in seconds).

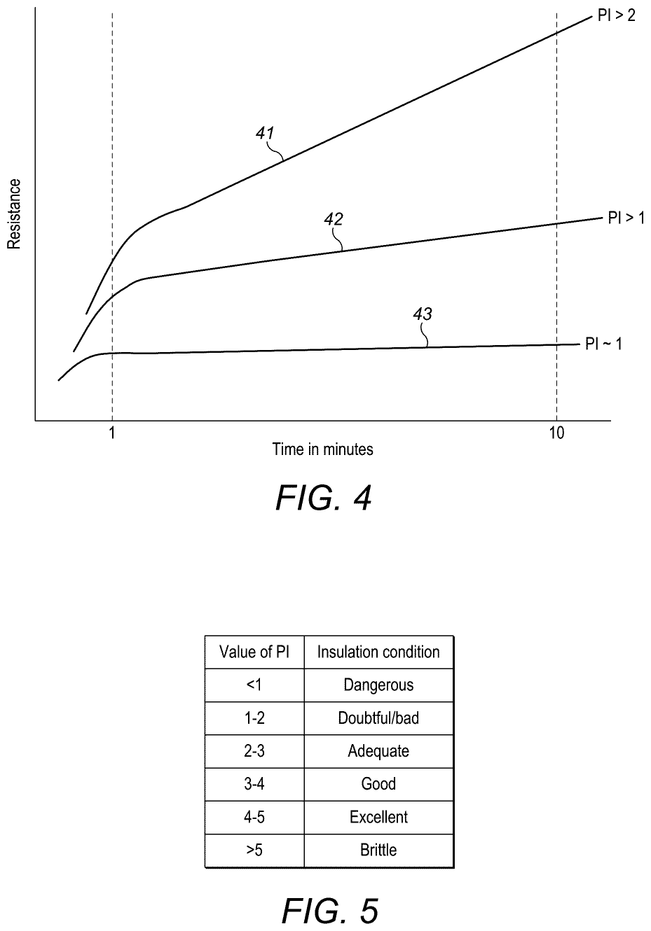

FIG. 4 illustrates curves 41, 42 and 43 representing measurements for PI values of >2, >1 and approximately 1 respectively.

The so-called Dielectric Absorption Ratio (DAR) is another example of a quality indicator for an insulator. The DAR is a ratio of 60 sec to 30 sec readings of resistance, such that DAR=R 60 sec/R 30 sec. DAR is much quicker to measure (1 min), but PI (10 min) gives more reliable information about the quality of the insulation system. Other quality indicators having other time ratios can be also used, for example R5 min/R1 min or R60 sec/R15 sec.

The value of the PI ratio (R10/R1) is larger if the leakage current is smaller, that is to say there is a higher value of the leakage resistor 30. It should be noted that it is the PI ratio which is the important parameter in indicating the condition of the insulator, not the resistance value itself. A flat response curve 43 usually denotes large leakage current, for example because of the moisture which is trapped in the insulation. Moisture is generally seen as being highly undesirable feature of an insulator, whereas dry and clean insulation is generally desirable and results in higher resistance as well as higher PI values.

FIG. 5 is a table showing an example of recommended PI values. For certain insulation materials, values PI>5 may indicate “brittle” insulation which was perhaps damaged due to overheating. Such insulation can be extremely dry and hence has very little leakage current, but its longevity would be compromised, so this also conveys some useful diagnostic information. This is as prescribed, for instance, in the standard IEEE 43.

The main disadvantage of the conventional PI test method involving measurements after 1 minute and 10 minutes is that it is very time consuming. For a 3-phase system each phase might need to be tested separately, which demands a minimum of 30 minutes test time for the whole machine.

In some cases, there may be additional measurements of depolarising currents carried out. This is done by short-circuiting the insulation system through an ammeter, discharging the main capacitor 30 as shown in FIG. 1. The voltage collapses very quickly, but the absorption RC branch 32 keeps delivering some small current, as dictated by its RC time constant. In a first approximation, the depolarisation (discharging) time constant is the same as the polarisation (charging). This can be used for detecting problems for multi-layer insulation systems. In general, the depolarisation takes as long as the polarisation. So, if the PI measurement takes 10 min, the depolarisation will take an additional 10 minutes, effectively doubling the measurement time. So, to fully test a 3-phase machine, at least 1 hour will be required.

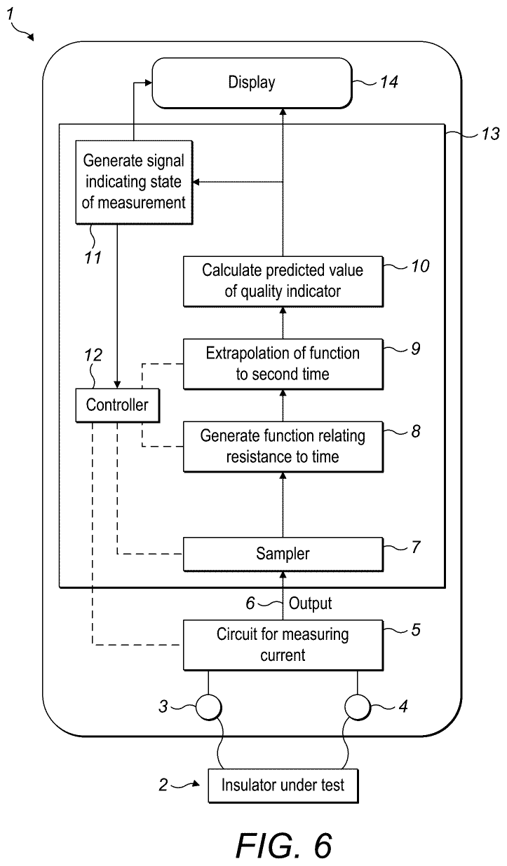

FIG. 6 shows a meter 1 according to an embodiment, in this example a digital meter, connected to an insulator under test 2. The meter is for performing a measurement of a quality indicator, in this example polarisation index (PI) for the electrical insulator 2. The meter has at least a first terminal 3 and a second terminal 4 for connection to the insulator under test, which may be, for example, the insulation of electrical windings of an electric motor. In this case, the terminals of the meter would be connected to the electrical windings on each side of the insulator under test. The meter has a circuit for measuring resistance 5, which may typically generate a high voltage to be applied to the insulator and measure the resulting, typically very small, current. The circuit for measuring resistance is connected to the first 3 and second 4 terminals. The circuit may not necessarily be directly connected to the first and second terminals, but may be connected via other components, for example an input protection circuit, which may comprise, for example, fuses. Two terminals are illustrated, but some examples may be provided with an additional terminal which may be referred to as a guard terminal provided in the interests of increasing measurement accuracy. The guard terminal may be held at the same potential as one of the terminals but bypassing the internal ammeter of the meter. The guard terminal may be connected to the surface of the insulator under test, so that unwanted surface leakage current does not influence the result of the test.

As shown in FIG. 6, the output 6 of the circuit for measuring resistance is connected to a sampler 7 to produce at least one sample of measured resistance. The sampler may be part of a processor 13. The processor 13 may comprise, for example, a microcontroller having program memory containing program code, or may be part of another processor or may be implemented by digital logic or by a programmable gate array. The functions of the processor 13 for performing digital signal processing and a controller 12 for the operation of the meter may be combined as one or more controller or processor circuits and may be performed by software or firmware configured to run on a programmable device.

The processor 13 in the meter iteratively performs steps of sampling the output from the circuit for measuring resistance to produce one or more further samples at successive increments in time and processes at least some of the samples to generate an approximate function relating measured resistance to time 8. The process for generating the approximate function may comprise least squares curve fitting, linear regression and/or non-linear regression.

The processor extrapolates the approximate function to encompass at least the second time 9 and calculates a predicted value for the quality indicator 10 on a basis comprising the resistance indicated by the approximate function for the second time.

The processor then generates an electrical signal indicating a state of the measurement 11 based on at least the predicted value of the quality indicator, which may indicate that the measurement is complete. In an example, the controller 12 stops the measurement in response to the electrical signal indicating a state of the measurement and in an example, the controller 12 stops the test and for safety initiates automatic discharge of the high-voltage charge accumulated in the insulator under test. The display shows an indication that the measurement is complete based on receiving the electrical signal.

The display 14 may show a graph of predicted quality indicator, typically polarisation index, against time as the measurement progresses. The processor may send a signal to the display so that the predicted value of the quality indicator is displayed at the end of the measurement as the measurement result, on the basis of the electrical signal indicating the state of the measurement indicating that the measurement is complete.

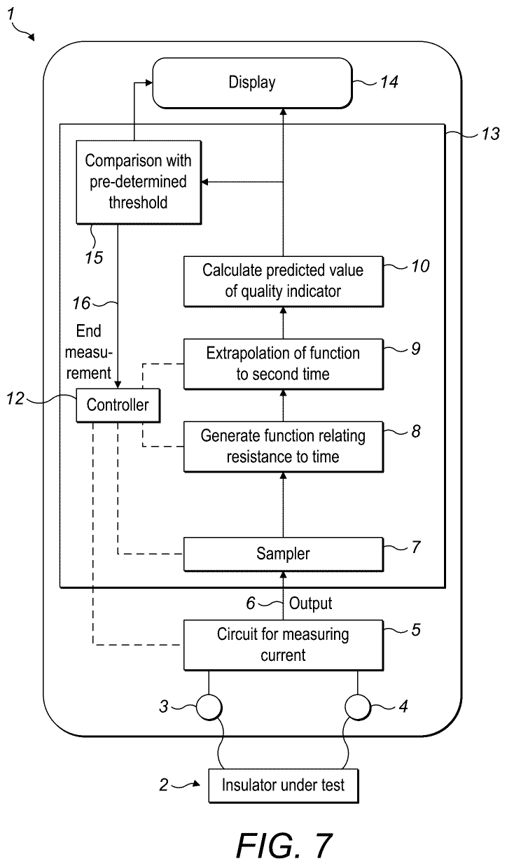

FIG. 7 shows an example of a meter in which the processor calculates a predicted value of the quality indicator 10 and compares the predicted value with at least one predetermined threshold. Based on the comparison, the processor sends a signal 16 indicating that the measurement should end. The controller 12, which is typically a functional block performed by the processor 13, then stops the measurement. In an example, stopping the measurement initiates a sequence of events: communicating the termination of the test to the user via the display, shutting down generation of high voltage (HV), activating a discharge mechanism and measuring capacitance of the insulator under test. While the output voltage remains “hazardous live” due to a high voltage being present, for example a voltage of greater than 50V, the instrument indicates the hazard, for example by the display having a flashing symbol or LED, and the test is fully finished after the output voltage is discharged to a safe level.

The threshold may be used to determine that the predicted quality indicator falls within certain ranges, for example polarisation index ranges corresponding to “bad” or “brittle” insulation. The display then shows the predicted polarisation index and/or its determined range as the measurement result.

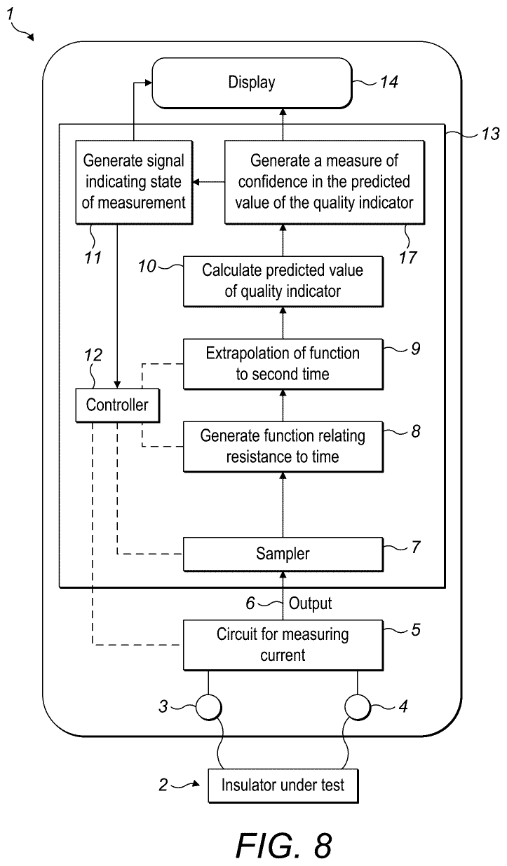

FIG. 8 shows an example of a meter in which the processor generates a measure of confidence in the predicted value of the quality indicator 17 and the generation of the electrical signal indicating a state of the measurement is based at least in part on the measure. In an example, the measure of confidence in the predicted value of the quality indicator is a confidence range of the predicted value of the quality indicator based on a measure of noise for at least some of the samples. If the noise level, as indicated for example by the statistical variation between samples, is higher, the measure of confidence would be lower and so the processor would allow the measurement to continue until an acceptable confidence level is generated. The confidence level may depend on the value of the predicted quality indicator or the measure of noise or both. In an example, a signal indicating the state of the measurement may be generated on the basis of the measure of noise and not on the basis of the predicted value of the quality indicator, and the measurement is stopped on the basis of the signal.

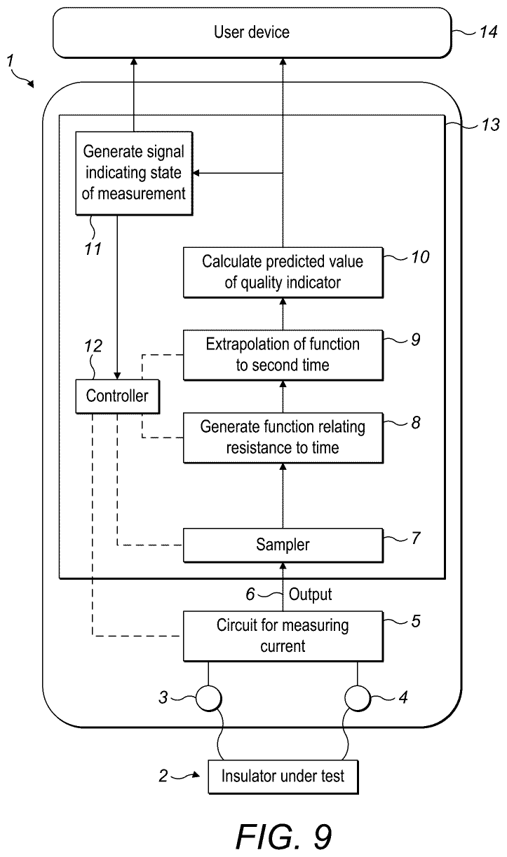

FIG. 9 shows a measurement apparatus comprising a meter 1 and a user device 37, such as a mobile telephone or a computer, the user device having one or more processors. The user device may be connected to the meter by a wireless link, for example Bluetooth or WiFi, or by a cable connection. The user device may be used to perform parts of the function of the meter, for example parts of the functions of the meters shown in FIGS. 6, 7 and 8, for example providing the display, or in other cases the display and at least parts of the function of the processor 13. In other cases, at least some of the functions of the processor may be processed as Internet-based cloud processing, in which the meter and/or the user device has a connection to the Internet. For example, the extrapolation function may be performed remotely from the meter in an external processor.

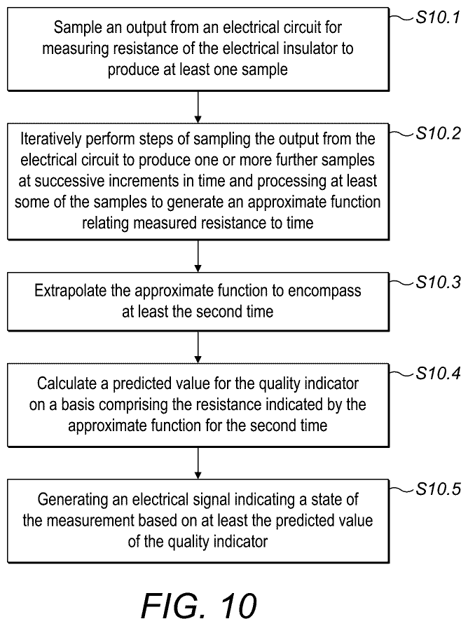

FIG. 10 is a flow diagram illustrating an example of a method of operating a meter, according to steps S10.1 to S10.5.

In an example, the processing of some of the samples to generate an approximate function relating measured resistance to time comprises discarding a set of samples, for example by discarding initial samples. The initial samples may not be helpful in predicting the resistance value at the second time. Discarding the samples allows more efficient processing.

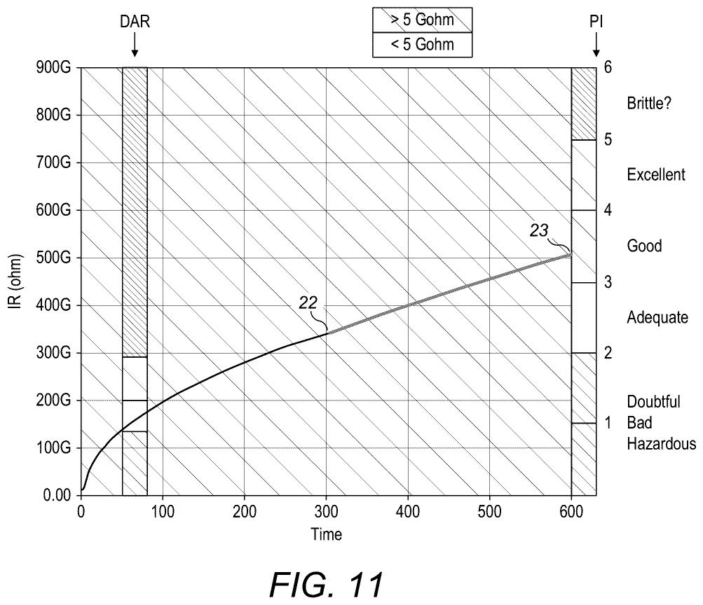

FIG. 11 illustrates prediction of a quality indicator indicating good insulator condition (PI=3-4). The vertical access shows resistance in GigaOhm and the horizontal access shows time in seconds. In this example, the second time for the PI calculation is at 600 seconds, at the right-hand end of the graph. The measurements taken are plotted on the curve up to the point shown by reference numeral 22. In this example, the measurements are stopped at 300 seconds. The curve is extrapolated from point 22 to point 23. The predicted value of resistance at the second time is at point shown by reference numeral 23, at approximately 500 GigaOhm. The measured resistance for the first time for PI calculation at 60 seconds is approximately 150 GigaOhm, so that the predicted PI value is 500/150=approx. 3.3. The illustration of FIG. 5 represents an example of the meter display, which shows the PI value as a scale on the right hand side of the display. The display is auto-scaled by the processor so that the point 23 where the extrapolated curve intersects with the PI scale can be used to read the predicted PI value.

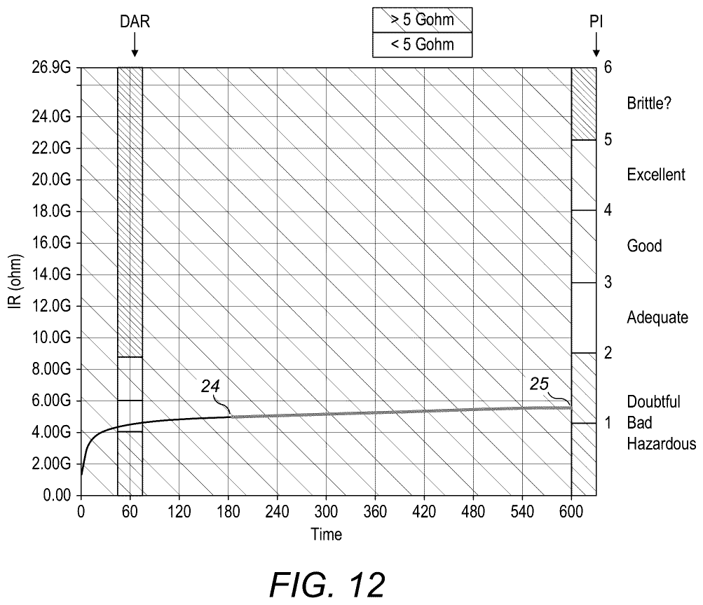

FIG. 12 illustrates prediction of a quality indicator indicating bad insulator condition (PI<2) in a reduced time in comparison to the time for prediction of a quality indicator indicating good insulator condition. The extrapolated curve gives a predicted PI value at point 25 of <1.5. The measurement is stopped at point 24 after 180 seconds.

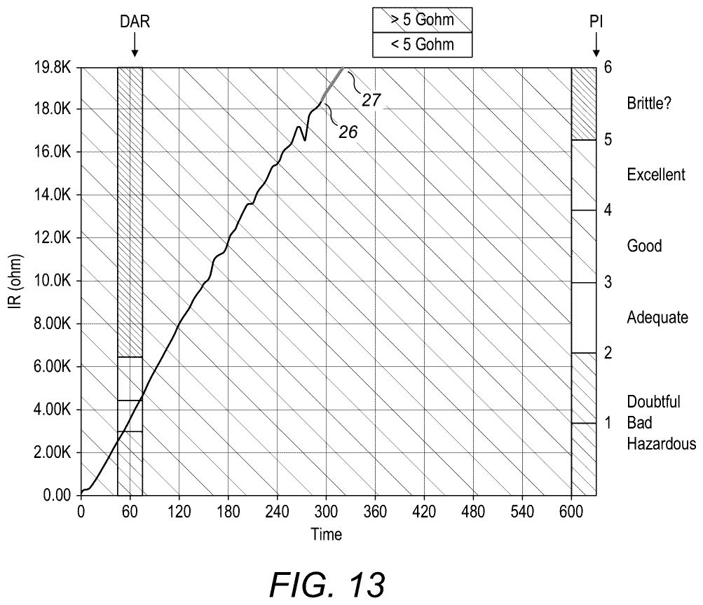

FIG. 13 illustrates prediction of a quality indicator indicating brittle insulator condition (PI>5). The extrapolated curve exceeds the top of the vertical scale at point 27, which, if extrapolated to the second time at 600s, would correspond to a PI value much greater than 6. It can be seen that the measurement is stopped at point 26 after about 300 seconds. It can be seen that there is some noise in the measured data. In the illustrated case, the measurement would have been stopped sooner, for example at 180 seconds, due to the PI prediction being greater than a predefined threshold, but a measurement of noise being greater than a threshold resulted in the measurement being extended to 300s, to give sufficient confidence on the predicted result.

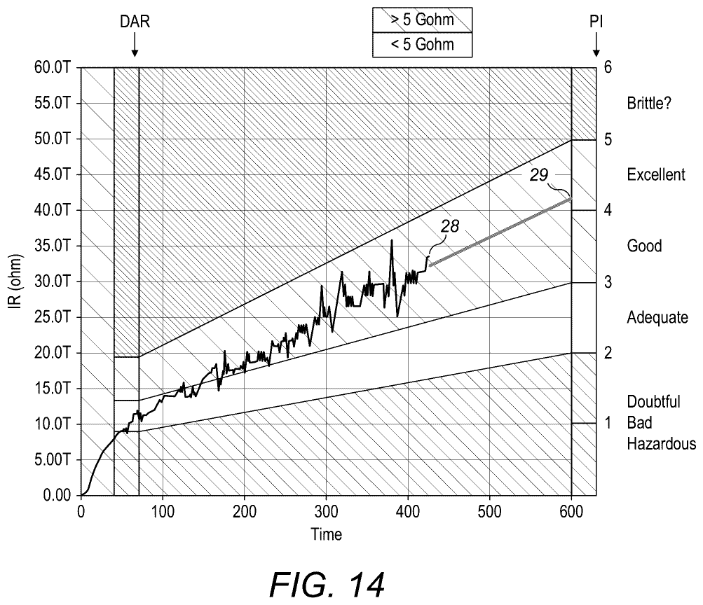

FIG. 14 illustrates an example of a meter display showing a prediction of a quality indicator from noisy samples. In this example, the measurement is stopped at point 28 after about 420 seconds. The PI prediction at point 29 has a value of about 4.2, which corresponds to an insulator condition classified as good. However, the measurement time is extended in comparison with the measurement time in the example of FIG. 5 because the noise level of the measurements, as shown by the statistical variation between samples, is higher than a predetermined threshold.

The following is a specific example of a method of operation.

1. Set the time at which the test automatically stops to an initial value, for example 300 s (5 minutes).

2. check noise level by calculating standard deviation of measured samples from the predicted curve.

3. If noise level is greater than or equal to a first threshold value, then extend time at which test automatically stops, for example to 360s. If noise level is greater than a second threshold value, then extend test time by a greater increment, for example to 420 seconds.

4. If noise value is less than the first threshold value, check predicted PI value, by extrapolating to 10 minutes. If predicted PI value is greater than an upper threshold, for example PI>5, and/or the predicted PI value is lower than a lower threshold, for example PI<1.25, PI<1.5 or PI<2, then reduce test time, for example to 180 seconds.

FIG. 14 shows that the intelligibility of the display may be improved by shading or colour coding of areas of the graph to show the likely PI value that would result from measurement values in that area at different points in the measurement. In the present example, the measurements fall predominantly in the shaded area leading to a PI value in the range 3-5. This gives an operator an indication of the likely outcome in terms of PI value as the measurement progresses.

It may be seen from the foregoing that present examples give a method of reliably predicting PI and have proved to be +/−10% accurate on a range of various curve shapes. For most curves the prediction can give a 10 min result just after 5 min of measurement. If the insulation is “bad” (for an example PI<1.5) then this can be detected just after 3 min of test time, and then there is no need to continue for the full 10 min. If the measurement is noisy then the test time can be automatically extended, to avoid premature incorrect prediction.

By the new method, an industrially accurate assessment of the insulation state can be achieved, but this can be done in a shorter actual time, which is not possible to be achieved by any other known method. As a result, the productivity of testing is greatly improved. Rapid identification of bad or brittle insulation systems is possible.

The approach of using a ratio (PI, DAR) is used instead of using absolute resistance values, because the resistance changes significantly with temperature. There may be roughly a 50% decrease for each 10 degrees C. The ratios are affected much less that the absolute values, which is why this method is very popular for diagnostic testing, especially in large motors and generators.

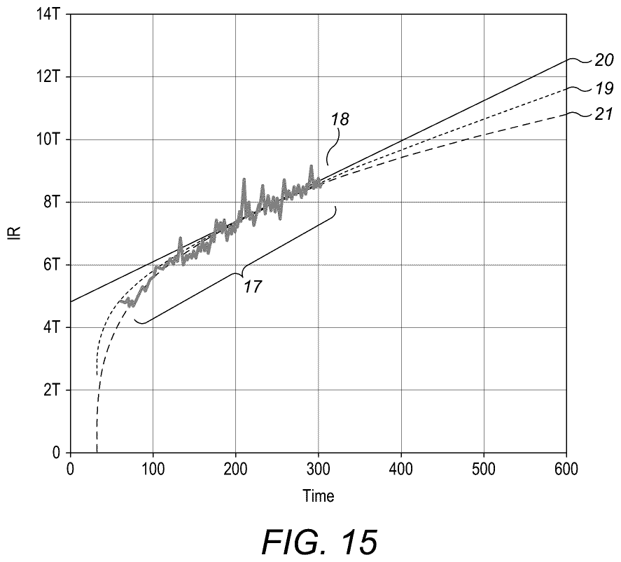

The new PI prediction method is conceptually illustrated in FIG. 15. The insulation resistance (IR) data is measured, from time 0 sec up to 600 sec (10 min). The measured IR data 17 is used to perform calculations. The initial part of the data, for example the initial 30 sec, or 60 sec, is ignored, in an example, because there are still some fast processes occurring in it, and they provide very little information about the values later in time. This is the reason why the measurement data 17 shown in FIG. 13 starts from 60 sec, because any data prior to 60 sec is not used in predicting the PI value in this example. The remainder of the measured data, in the example of FIG. 15 from 60 sec to 300 sec, is used to perform curve fitting by means of linear or non-linear regression. An appropriate type of function is chosen, for example power, polynomial, exponential or linear, to give the best possible fit to the measured data. More than one function can be used for the approximation and then the best fit can be selected, for example by means of least-square method, to be used for prediction of the PI value. An average between two or more functions can be applied, for example by means of weighted average depending on quality of curve fitting, for instance as measured by the so-called residuals from the non-linear/linear regression.

The final approximated function is then taken, and its value is extrapolated to the final time, for example 600 sec/10 min, before the value at the final time would be due to be measured. This extrapolated/predicted value is denoted by the rectangle on extrapolated curve 19 in FIG. 15, at 600 sec. Therefore, it can be seen from FIG. 15 that the 10 min reading can be predicted well before it would be measured by the hardware.

The measured data can be processed in real time so that the user gets a visual feedback what is the likely outcome of the measurement, even before the measurement, with the prediction enabled, is actually finished. The data is analysed dynamically, for example with the readings updated every 1 sec, so that if there is little noise then the measurement finishes after 3-5 mins, and if it is noisier the algorithm will automatically demand from the hardware to continue testing beyond 5 mins, potentially all the way to 10 mins, so that even in extremely noisy conditions a good measurement can be provided. This has already been described in connection with FIG. 14.

Returning to FIG. 14, this shows that the DAR (also called DA in the USA) and PI scales can be colour-coded and placed on the same screen (the arrows at the top of FIG. 14 indicate these two scales). Additionally, the whole background can be split into coloured regions, which offer very clear visual feedback to the operator on where the predicted curve is likely to finish when extrapolated to the 10 min time. The scaling can be both in the insulation resistance (left) or PI or DAR ratio (right). In FIG. 14, the PR and DAR scales are in the same units, because they are both ratios, so “1” on one scale corresponds to “1” on the other. However, smaller DAR values correspond to larger PI values, for example, DAR>1.75 indicates “good”, whereas it is required PI>3 for “good”.

FIG. 14 shows a meter display for an initial part of the measurement shown complete in FIG. 5, and FIG. 15 shows a meter display for an intermediate part of the measurement shown complete in FIG. 5. It can be seen that in the example of FIG. 14, just the raw data displayed point-by-point until 180 sec after which the prediction starts. FIG. 15 shows the state of the measurement at 240 sec when the prediction reaches 390 sec, FIG. 5 shows the finished measurement, showing the prediction made from 300 sec to 600 sec.

For very bad insulation (PI<1.5) the measurement can finish after just 3 min, as already mentioned. Similarly, if PI is very high, then the prediction can be reported as PI>7 or PI>5, in examples.

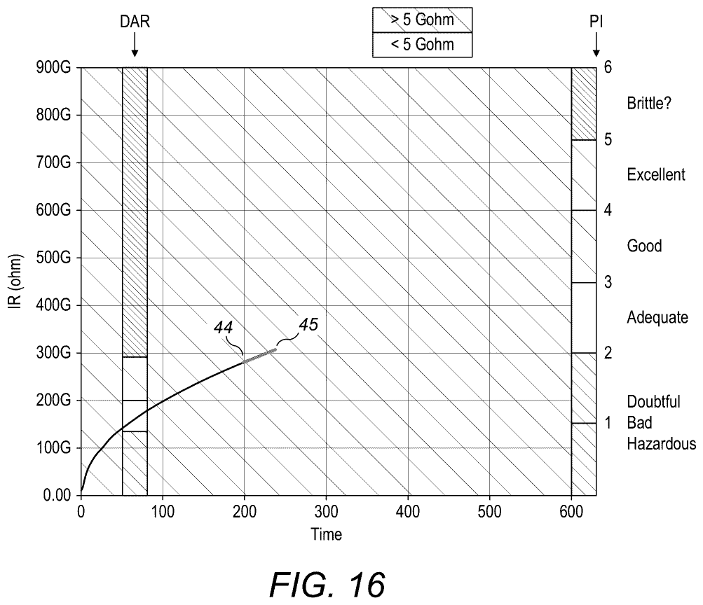

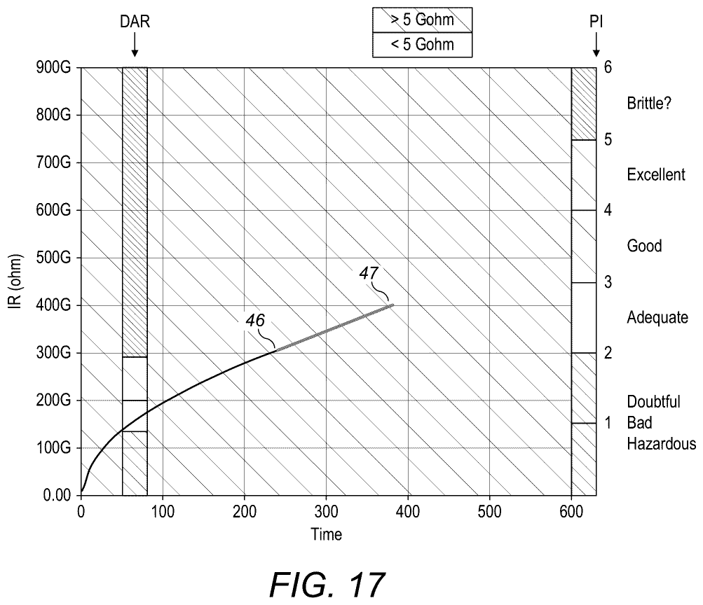

The initial data in the measured IR curve contains less useful information than the data farther in time, so that the initial measured data, for example up to 90 sec, can be ignored, because of the presence of fast-changing currents. Throughout the whole measurement, the data at the end of the given measurement brings more information about the likely shape of the curve than the initial data. Therefore, the measured data can be dynamically processed such that the data is used with weighting coefficients which favour the data towards the end of the curve. In an extreme case the first portion of the data, for example the first half, can be ignored in the curve fitting procedure. FIGS. 16 and 17 illustrate a sequence of predictions of resistance value for times increasingly far into the future during the measurement which has previously been described in connection with FIG. 11. FIGS. 16, 17 and 11 can be viewed as an animation, showing how a display would progress during a measurement. A prediction of resistance value at a given level of confidence may be made increasingly far into the future as the measurement progresses, until a prediction at the second time, typically 10 minutes, can be made with the given level of confidence. At low noise levels, the time up to which the resistance is predicted may depend on the number of measurement samples of the electrical parameter, typically current or resistance, that have been taken. If the noise is above a predetermined threshold, then the time up to which the resistance is predicted may depend on the noise level, so that, with higher levels of noise, the prediction can be made with a given confidence level less far into the future than can be made with lower noise levels. The time to which the approximate level is extrapolated may be dependent on the measure of confidence in the predicted value of the quality indicator, which may be based on a measure of noise for at least some of the samples. During the sequence shown by FIG. 16, FIG. 17 and then FIG. 11, initially the data between 60-240 sec will be used for curve fitting, that is to say to generate the approximate function, as shown in FIG. 16, but in the final stages shown in FIG. 11, in an example only the data between 200-300 sec will be used, for curve fitting. This can be automatically scaled by the software. The samples used to generate the approximate function are typically used to generate the measure of noise to be used to generate the measure of confidence in the predicted value of the quality indicator.

In an example, the curve approximating function is chosen to be a power curve such that:

$$y = a * {x}^{b} + c \qquad ( 1 )$$

where: y represents the measured IR values, x is the time, and a,b,c are the function coefficients, hence:

$$IR ( t ) = a * {t}^{b} + c \qquad ( 2 )$$

The a,b,c coefficients can be found through statistical and mathematical methods as defined with the non-linear regression models, which are well known.

As can be seen from FIG. 17, the length of the prediction is limited, so that the final value is not reported until the algorithm is satisfied with the quality of the prediction. Only then the predicted function is extrapolated all the way to 600 sec. The way in which the extrapolation is limited is governed by a function, further limited by a set of conditions. The extrapolated data starts from the last measured point (time_now). The interval over which the predicted function is used, that is to which point should be plotted as in FIG. 17 (i.e. its “final” point, time t2, such that t2<=600) can be described by the following function:

$$t 2 = \{ t 1 + ( 600 - end\_at \_time ) * ( time\_now - 180 ) / ( end\_at \_time - 180 ) \} \qquad ( 3 )$$

where: t1 is synonymous with the location of time_now (but is related to the number of points in the array of the data used for curve fitting; herein it is assumed that we get 1 data point for 1 sec of time), and the number 180 denotes the number of points after which the prediction begins (see FIG. 16). The value end_at_time specifies the length of time after the test is to be stopped (provided that there is no noise and the PI value is not too low, and for instance end_at_time=300).

The end_at_time value can be modified by IF conditions in the following manner. If the noise in the data is detected to be above the first threshold then extend the test time (value of end_at_time) by the first amount (e.g. from 300 to 360).

If the noise in the data is detected to be above second threshold then extend the test time by the second amount (e.g. from 300 to 420). Additionally, the check can be performed for “bad” PI values (PI ratio below 1.25, 1.5, or 2 in examples).

For a “bad” PI the measurements are likely to be less noisy because the current is high. Therefore, if the noise is below the first threshold and the PI is below the “bad PI threshold” then the test is permitted to be stopped after just 180 sec, which may be shortly after the prediction is started. The mathematical functions used for approximation/extrapolation can be selected as, for example, power, exponential, polynomial, or linear. The curve fitting can be performed also on the data of current, rather than resistance, because these two values are the reciprocal of each other.

A combination of functions can be used, as has been described in connection with FIG. 15. In that example there is a power function 21 and the linear function 20, which are both fitted to just the second half of the measured data 17. The “residual” values (quality of curve fitting represented for example by the least square calculations) are taken into account and are used as weights for calculating a weighted average between these two functions. In the particular case of FIG. 15, because of the noise in the green data both functions have similar residuals. Therefore, the weighted average function 19 is very close to point-by-point average of both functions. Therefore, the extrapolation is effectively calculated as the weighted average of two extrapolations towards 600 sec.

Returning to FIG. 14, this illustrates the generation of automatic scales in the display. FIG. 14 shows 3 vertical scales. The first scale (on the left) is specified in the units of 2 (ohms). The second scale (on the right, PI) is located at the end of the graph at 600 sec, which could be at 300 sec or some other time in other examples. The PI scale is in the units of ratio, with respect to the reading at 60 sec, or whatever the reference point was specified by the user. The third scale (DAR) is located at the reference point (60 sec, adjusted by the user).

The behaviour of autoscaling can be as follows. At the beginning of the test the value for the reference point is unknown, so it is not possible to position the ratio scales (PI, DAR). So, the first scale (Ω) can be just autoscaling, with the other two scales suppressed (not shown, or greyed out, or similar). Alternatively, the first axis (Ω) can be always scaled such that in the interval from 0 sec to 60 sec the currently measured value (last value of real data on the graph) is always scaled to correspond to ratio=1.

If DAR and PI scales were configured to have the same reference point (e.g. 60 sec), then as soon as this reference point is reached, then both scales can be shown, and the whole graph to be scaled such that that the value in Ω at 60 sec corresponds precisely to ratio=1 (for both DAR and PI). From this point onward, the scales of axes remain fixed, and the animation progresses similarly as shown in FIGS. 16 and 17.

The second scale (DAR) may have different reference points to the third scale (PI). For example, DAR can be calculated as 30 sec/15 sec, and PI as 300 sec/60 sec. Then the DAR and PI scales will have to be different in terms of ranges of ratio values (rather than both extending from 0 to 6, for example), as dictated by the measured values. Both, DAR and PI scales, can have similar colour coding, and joined by “colour areas” for easier interpretation, for example similar to FIG. 14, but with DAR rescaled to different values.

A simplified approach to extrapolation of data to predict PI may be used. The curvature of plots of the measurement data tends to decrease with time, so that the changes occur at a slower pace and the curve tends more and more to a “plateau”. This can be approximated with a straight line. The straight line can be derived by means of linear regression, which is based on statistical processing of the data, for example based on average values. However, a straight line can be obtained also through a simplified algorithm, which does not require storing the full array of data, but instead it is based on recursive calculations. Such approach would vastly reduce requirements on digital memory, because only a handful of distinct variables would have to be stored to perform the prediction/extrapolation, rather than a full array of data. Such methods do not have to be mathematically strict, but they can provide enough “quality” of prediction that in practice can be found to work sufficiently well to be useful.

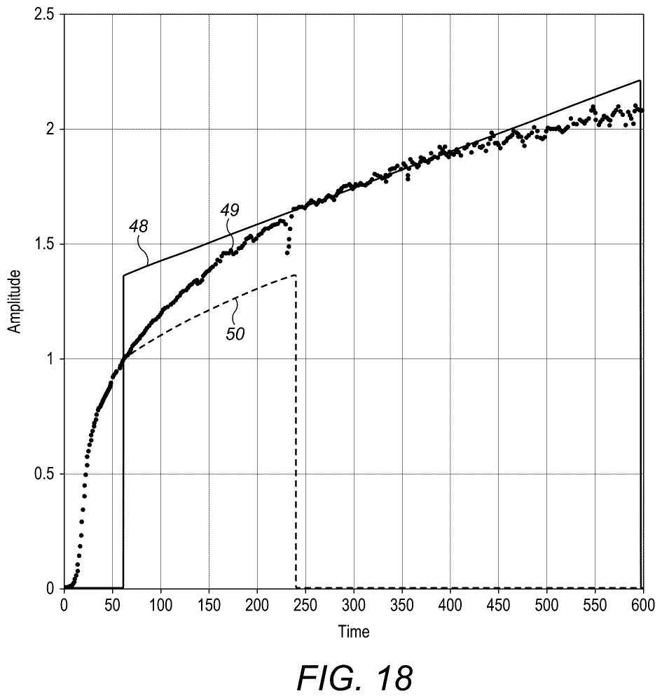

Such a simplistic linear model is shown in FIG. 18. In this case, the initial 60 sec of data is ignored. From the point of 60 sec onwards the data is processed such that a running average (moving average) is calculated by means of recursive calculation, so that only a single variable is stored in the memory. The way this variable changes is represented by curve 50 in FIG. 18. In the presented case, at the time of 240 sec the prediction/extrapolation is made to 600 sec. The values stored in the moving average variable is taken and simply assigned as if it would belong to the 60 sec location (the peak of the curve 50 at 240 sec becomes the first point on of the ramp of the curve 48 at 60 sec). Then a straight line is extended from this new starting point, passing through the currently measured actual value of IR at 240 sec, at which the line 48 crosses the measured points 48, and is extrapolated to 600 sec.

This can be calculated by using the two-point approach from a function y=a+b. As can be seen from FIG. 18, the point of the curve 48 extrapolated to 600 sec provides a useful estimation of the predicted value of PI. In the presented case the actual value was PI=2.09 whereas the simplistic model returned PI=2.22. If just a single digit resolution was used, then the ideal value would be PI=2.1, versus the predicted PI+=2.2.

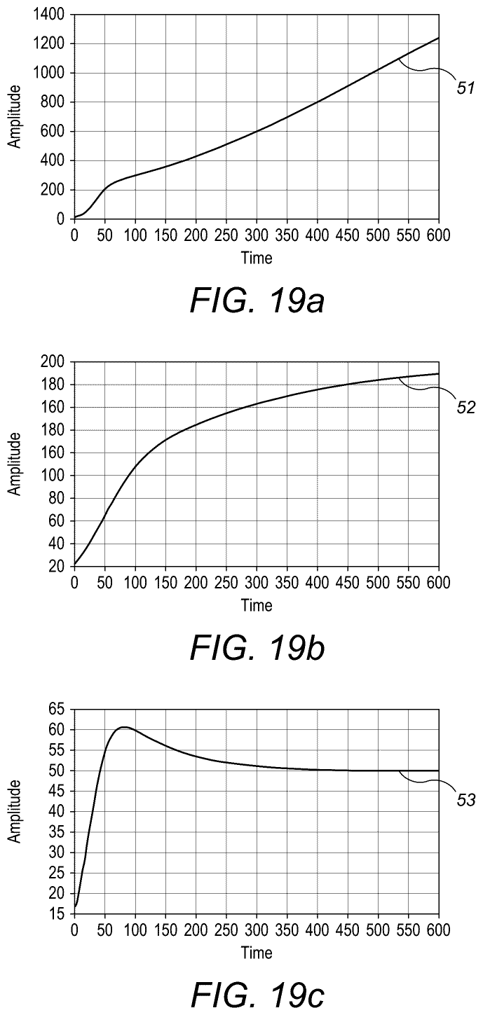

The absorption effect can be modelled by more than one RC branch, as already mentioned. An assumption could be made that all such processes should happen exponentially and hence if a value of RC constant for each branch could be estimated from the measured data then a very good fit could be obtained. For example, two RC branches can be modelled, and the resulting total current can be calculated, and then resistance can be calculated from the current. Such a simple model, in which the main capacitor 31 is ignored, and one main resistor, and two parallel RC branches are provided, can produce a whole family of very different characteristics, which can mimic the real behaviour, with the same model and just varying the RC parameters. Typical examples are shown in FIGS. 19a, 19b and 19c, showing different curves 51, 52 and 53. With this R+2RC model the components of current can be analysed and extracted from the total current curve. All the components should be pure exponential curves, which in theory should be extractable from the main curve. A Fourier transform technique for aperiodic signals could be used. In other examples, a Prony, Laplace, S, and Z transform techniques may be used.

As mentioned already, the measurement equipment may comprise one or more processors for causing the equipment to perform the methods as described. The one or more processors may comprise, or be in communication with, a computer-readable storage medium, such as a memory chip or other data storage device. At least one of the one or more processors may be situated within a user device 37, such as a smart phone, connected to a meter 1. The computer-readable storage medium may hold instructions for causing one or more processors to cause the measurement apparatus to receive a sample of an output from an electrical circuit for measuring the electrical parameter for the electrical insulator to produce at least one sample and to receive further samples at successive increments in time and process at least some of the samples to generate an approximate function relating the measured electrical parameter to time. The samples may be received by the user device 37 from the meter 1. The instructions may cause the measurement apparatus to calculate a predicted value for the quality indicator on a basis comprising the electrical parameter indicated by the approximate function for the second time and generate an electrical signal indicating a state of the measurement based on at least the predicted value of the quality indicator. The instructions may cause one or more processors to cause the measurement apparatus to sample an output from an electrical circuit for measuring the electrical parameter for the electrical insulator to produce at least one sample and send the sample to at least one of the one or more processors and

sample the output from the electrical circuit to produce one or more further samples at successive increments in time and send the one or more further samples to at least one of the one or more processors. Sending the samples may be by a wired connection, or by a radio link such as Bluetooth or WiFi, or by any other method. Parts of the instructions may be performed by a processor at the meter and parts of the instructions may be performed by a processor at the user device.

The above embodiments are to be understood as illustrative examples of the invention. It is to be understood that any feature described in relation to any one embodiment may be used alone, or in combination with other features described, and may also be used in combination with one or more features of any other of the embodiments, or any combination of any other of the embodiments. Furthermore, equivalents and modifications not described above may also be employed without departing from the scope of the invention, which is defined in the accompanying claims.

1. A method of operation of a measurement apparatus for performing a measurement of a quality indicator for an electrical insulator, the quality indicator comprising a ratio of a first value of an electrical parameter at a first time to a second value of the electrical parameter at a second time, the method comprising:
sampling an output from an electrical circuit for measuring the electrical parameter for the electrical insulator to produce at least one sample;
performing steps of sampling the output from the electrical circuit to produce one or more further samples at successive increments in time and processing at least some of the samples to generate an approximate function relating the measured electrical parameter to time;
calculating a predicted value for the quality indicator on a basis comprising the electrical parameter indicated by the approximate function for the second time; and
generating an electrical signal indicating a state of the measurement based on at least the predicted value of the quality indicator.

2. The method of claim 1, wherein the electrical parameter is a current.

3. The method of claim 1, wherein the electrical parameter is a resistance.

4. The method of claim 1, comprising generating a measure of confidence in the predicted value of the quality indicator,
wherein the step of generating an electrical signal indicating a state of the measurement is based on at least the measure of confidence in the predicted value of the quality indicator.

5. The method of claim 4, wherein the measure of confidence in the predicted value of the quality indicator is a confidence range of the predicted value of the quality indicator based on a measure of noise for at least some of the samples.

6. The method of claim 1, wherein the electrical signal indicating a state of the measurement indicates that the measurement is complete.

7. The method of claim 6, comprising stopping the measurement in response to the electrical signal indicating a state of the measurement.

8. The method of claim 1, comprising generating an electrical signal causing display of the predicted value for the quality indicator in dependence on the electrical signal indicating the state of the measurement.

9. The method of claim 1, wherein said processing some of the samples to generate an approximate function relating measured resistance to time comprises discarding a set of samples.

10. The method of claim 1, wherein said processing at least some of the samples to generate an approximate function relating measured resistance to time comprises least squares curve fitting.

11. The method of claim 1, wherein said processing at least some of the samples to generate an approximate function relating measured resistance to time comprises linear regression.

12. The method of claim 1, wherein said processing at least some of the samples to generate an approximate function relating measured resistance to time comprises non-linear regression.

13. The method of claim 1, wherein the quality indicator for the electrical insulator is a polarisation index.

14. The method of claim 1, wherein the quality indicator for the electrical insulator is a dielectric absorption ratio.

15. Measurement apparatus for performing a measurement of a quality indicator for an electrical insulator, the quality indicator comprising a ratio of a first value of an electrical parameter at a first time to a second value of the electrical parameter at a second time, the measurement apparatus comprising at least one processor configured to cause the measurement apparatus to:
sample an output from an electrical circuit for measuring the electrical parameter for the electrical insulator to produce at least one sample;
perform steps of sampling the output from the electrical circuit to produce one or more further samples at successive increments in time and processing at least some of the samples to generate an approximate function relating the measured electrical parameter to time;
calculate a predicted value for the quality indicator on a basis comprising a value of the electrical parameter indicated by the approximate function for the second time; and
generate an electrical signal indicating a state of the measurement based on at least the predicted value of the quality indicator.

16. The measurement apparatus of claim 15, wherein the electrical signal indicating a state of the measurement indicates that the measurement is complete, wherein the at least one processor is configured to cause the measurement apparatus to stop the measurement in response to the electrical signal indicating a state of the measurement.

17. The measurement apparatus of claim 15, wherein the at least one processor is configured to cause the measurement apparatus to generate an electrical signal causing display of the predicted value for the quality indicator in dependence on the electrical signal indicating the state of the measurement.

18. The measurement apparatus of claim 15, wherein the measurement apparatus is a meter.

19. The measurement apparatus of claim 15, wherein the measurement apparatus comprises a meter and a user device comprising a processor in communication with a processor in the meter.

20. A computer-readable storage medium holding instructions for causing one or more processors to cause measurement apparatus for performing a measurement of a quality indicator for an electrical insulator, the quality indicator comprising a ratio of a first value of an electrical parameter at a first time to a second value of the electrical parameter at a second time, to:
receive a sample of an output from an electrical circuit for measuring the electrical parameter for the electrical insulator to produce at least one sample;
receive further samples at successive increments in time and process at least some of the samples to generate an approximate function relating the measured electrical parameter to time;
calculate a predicted value for the quality indicator on a basis comprising the electrical parameter indicated by the approximate function for the second time; and
generate an electrical signal indicating a state of the measurement based on at least the predicted value of the quality indicator.
